(19) United States
(12) Patent Application Publication
(10) Pub. No.: US 2014/0048898 A1
(43) Pub. Date: Feb. 20, 2014

(54) BACKSIDE ILLUMINATED CMOS IMAGE SENSOR

(71) Applicant: OmniVision Technologies (Shanghai) Co., Ltd., Shanghai (CN)

(72) Inventors: Xiaoai Fei, Shanghai (CN); Jing Ye, Shanghai (CN)

(73) Assignee: OmniVision Technologies (Shanghai) Co., Ltd., Shanghai (CN)

(21) Appl. No.: 13/945,860

(22) Filed: Jul. 18, 2013

(30) Foreign Application Priority Data
Aug. 15, 2012 (CN) 201210290693.3

(51) Int. Cl. H01L 31/0232

(52) U.S. Cl. CPC H01L 31/02327
USPC 257/432

(57) ABSTRACT

A backside illuminated (BSI) CMOS image sensor is disclosed. The BSI CMOS image sensor includes: a substrate having a front side and a back side, the substrate including a photodiode formed therein, the photodiode being proximate the back side of the substrate; a metal shielding layer covering the back side of the substrate, the metal shielding layer including an opening formed therein, the opening being arranged in correspondence with the photodiode; and a light-absorbing layer formed on each side face of the opening. The light-absorbing layer coated on the side faces of the opening prevents the occurrence of photon cross-talk and hence improves imaging quality of the BSI CMOS image sensor.

### CROSS-REFERENCES TO RELATED APPLICATIONS

This application claims the priority of Chinese patent application number 201210290693.3, filed on Aug. 15, 2012, the entire contents of which are incorporated herein by reference.

### TECHNICAL FIELD

The present invention relates in general to image sensors, and more particularly, to a backside illuminated (BSI) CMOS image sensor.

### BACKGROUND

Digital cameras are a kind of modern electronic products and are widely used. A digital camera typically incorporates an image sensor for converting light to electric charges. According to their different operating principles, image sensors are classified into charge-coupled device (CCD) sensors and complementary metal oxide semiconductor (CMOS) sensors. CMOS image sensors are fabricated using conventional CMOS technologies and therefore can be integrated with peripheral circuitries during the fabrication.

Conventional CMOS image sensors typically rely on a front-side illumination (FSI) technology to provide pixels for a pixel array. In the FSI technology, incident light enters a pixel from the front side and then reaches a photo-sensing area. In other words, before reaching the photo-sensing area, the incident light must pass through several dielectric layers and metal layers. Such design leads to many problems of the conventional CMOS image sensors, such as low quantum efficiency, severe cross talk and dark current.

In order to solve the above-mentioned problems, a CMOS image sensor adopting a backside illumination design, also referred to as a backside illuminated (BSI) CMOS image sensor, has been proposed in the prior art. Different from the FSI sensors discussed above, the BSI CMOS image sensor is formed on a front side of a silicon substrate, while color filters and microlenses are arranged on a back side of the substrate, thereby allowing incident light to enter the sensor from its back side. This BSI CMOS image sensor has a number of advantages compared with conventional FSI ones, such as less light loss and better quantum efficiency.

Nevertheless, the BSI CMOS image sensor still has a serious problem of color cross-talk, and therefore an existing BSI CMOS image sensor typically includes an additional metal shielding layer for solving this problem of color cross-talk. However, adding the metal shielding layer further causes a problem of photon cross-talk.

### SUMMARY OF THE INVENTION

The present invention is directed to the provision of a BSI CMOS image sensor which can solve the problem of the photon cross-talk of the existing BSI CMOS image sensor.

To achieve the above objective, there is provided a BSI CMOS image sensor including: a substrate having a front side and a back side, the substrate including a photodiode formed therein, the photodiode being proximate the back side of the substrate; a metal shielding layer covering the back side of the substrate, the metal shielding layer including an opening formed therein, the opening being arranged in correspondence with the photodiode; and a light-absorbing layer formed on each side face of the opening.

Optionally, the opening is vertically aligned with the photodiode.

Optionally, the BSI CMOS image sensor further includes a high-k dielectric layer between the device substrate and the metal shielding layer.

Optionally, a portion of the high-k dielectric layer is exposed in the opening.

Optionally, the light-absorbing layer is a nitride layer.

Optionally, the light-absorbing layer is a silicon oxynitride layer, a silicon nitride layer, a titanium nitride layer, or a tantalum nitride layer.

Optionally, the light-absorbing layer has a thickness of 200 Å to 700 Å.

Optionally, the light-absorbing layer is formed by a PECVD process or a furnace process.

Optionally, an angle between the side face and a bottom face of the opening is greater than 90 degrees and smaller than 180 degrees.

Optionally, a top face of the metal shielding layer is also covered by the light-absorbing layer.

Optionally, the metal shielding layer is made of aluminum or tungsten.

By forming a light-absorbing layer on both side faces of each opening, the present invention is capable of preventing the occurrence of photon cross-talk and hence improving imaging quality of the BSI CMOS image sensor.

### BRIEF DESCRIPTION OF THE DRAWINGS

FIG. 1 is a cross-sectional view of an existing BSI CMOS image sensor.

FIG. 2 is a cross-sectional view of a BSI CMOS image sensor constructed in accordance with one embodiment of the present invention.

FIG. 3 depicts a flow chart of a method for forming a BSI CMOS image sensor in accordance with one embodiment of the present invention.

FIGS. 4a to 4c are cross-sectional views schematically illustrating structures after steps of the method of FIG. 3.

### DETAILED DESCRIPTION

The present invention will be described in detail below by way of specific embodiments with reference to the accompanying drawings. Advantages and features of the invention will be readily apparent upon reading of following description and appended claims. It is noted that drawings are provided in a very simplified form and are solely for enhancing convenience and clarity of the description of the specific embodiments.

As indicated above in the Background, although the existing BSI CMOS image sensor has addressed the issue of color cross-talk, its inclusion of the metal shielding layer further leads to the problem of photon cross-talk. In order to solve this problem, the inventors of this invention had an in-depth study on this subject and identified the cause of the occurrence of photon cross-talk in the existing BSI CMOS image sensor, which is described in detail below.

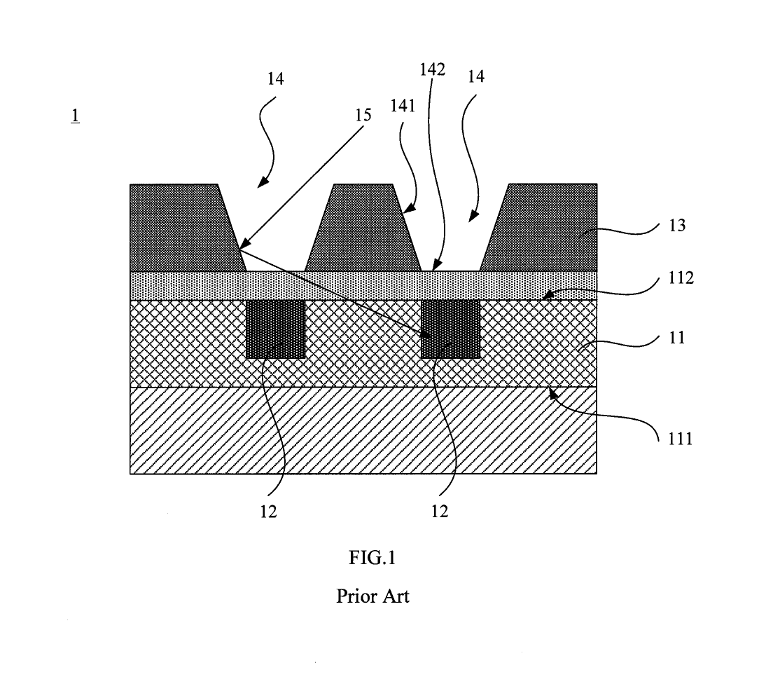

FIG. 1 shows a cross-sectional view of an existing BSI CMOS image sensor 1. As shown in FIG. 1, the BSI CMOS image sensor 1 includes: a device substrate 11 having a front side 111 and a back side 112, wherein photodiodes 12 are formed in the device substrate 11 and proximate the back side 112 of the device substrate 11; and a metal shielding layer 13 covering the back side 112 of the device substrate 11, wherein openings 14 are formed in the metal shielding layer 13 and correspond to the photodiodes 12.

The openings 14 in the metal shielding layer 13 may be formed by the following steps: forming the metal shielding layer 13; and forming the openings 14 in the metal shielding layer 13 by an etching process.

Due to the nature (or inherent feature) of the etching process, each of the formed openings 14 has an inverted-trapezoid shape (as described per the profile and orientation of the opening shown in FIG. 1). In other words, an angle between a side face 141 and a bottom face 142 of the opening 14 is greater than 90 degrees and smaller than 180 degrees. Such shape of the opening 14 causes a portion of incident light 15 to be incident on the side face 141. The portion of incident light 15 will be thereafter reflected by the side face 141 onto another photodiode 12 other than the photodiode 12 corresponding to the opening 14. For example, with further reference to FIG. 1, a light beam 15 enters a neighboring photodiode 12 after it is reflected by the side face 141 of the opening 14. This is just the reason for the occurrence of the photon cross-talk that harms imaging quality of the existing BSI CMOS image sensor.

Based on this finding of the inventors, there is provided a BSI CMOS image sensor which can address the issue discussed above and is described below by way of non-limitative exemplary embodiments with reference to the accompanying drawings.

### Embodiment 1

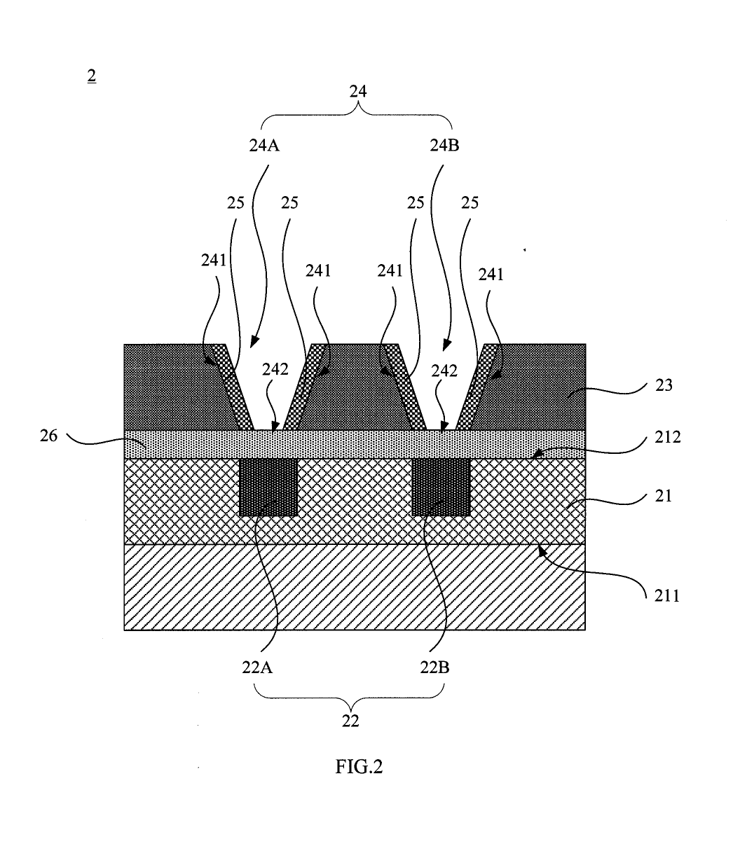

FIG. 2 shows a cross-sectional view of a BSI CMOS image sensor 2 embodying the present invention. The BSI CMOS image sensor 2 includes: a device substrate 21 having a front side 211 and a back side 212, wherein one or more photodiodes 22 are formed in the device substrate 21 and proximate the back side 212; and a metal shielding layer 23 covering the back side 212 of the device substrate 21, wherein one or more openings 24 are formed in the metal shielding layer 23 and correspond to the photodiode 22, and wherein both side faces 241 of each opening 24 are covered by a light-absorbing layer 25.

In this embodiment, the metal shielding layer 23 is comprised of aluminum, while in other embodiments the metal shielding layer 23 may also be made of copper, titanium, or the like. An angle between the side face 241 and the bottom face 242 of the opening 24 is greater than 90 degrees and smaller than 180 degrees.

The light-absorbing layer 25 is able to prevent light from being reflected by the side face 241 of the opening 24 into another photodiode 22 other than the photodiode 22 corresponding to the opening 24, thereby preventing the occurrence of photon cross-talk and improving imaging quality of the BSI CMOS image sensor.

Specifically, for example, if neither of two of the openings 24 shown in FIG. 2, namely, the first opening 24A that corresponds to a first photodiode 22A and the second opening 24B that corresponds to a second photodiode 22B, is covered with a light-absorbing layer 25, there is a great possibility for the light incident on the side face 241 of the first opening 24A to be reflected by the side face 241 into the second photodiode 22B, and similarly, there is also a great possibility for the light incident on the side face 241 of the second opening 24B to be reflected by the side face 241 into the first photodiode 22A. This is prevented in this embodiment by including the light-absorbing layer 25 in the BSI CMOS image sensor. In other words, the light-absorbing layer 25 is able to prevent the incident light from being reflected by the side face 241 of the opening 24 into another photodiode 22 other than the photodiode 22 corresponding to the opening 24, thereby preventing the occurrence of photon cross-talk and improving imaging quality of the BSI CMOS image sensor.

Preferably, the first and second openings 24A, 24B are vertically aligned with the first and second photodiodes 22A, 22B, respectively, so as to improve light reception and photoelectric conversion of the photodiodes and hence improve imaging quality of the BSI CMOS image sensor.

In this embodiment, a high-k dielectric layer 26 may be provided between the device substrate 21 and the metal shielding layer 23. The high-k dielectric layer 26 can further optimize the photoelectric conversion of the photodiodes and hence further improve imaging quality of the BSI CMOS image sensor. In addition, the opening 24 may expose a portion of the high-k dielectric layer 26. Specifically, the first opening 24A exposes a portion of the high-k dielectric layer 26 that is right above the first photodiode 22A such that the first photodiode 22A can be further exposed after the portion of the high-k dielectric layer 26 is removed in a subsequent process. Similarly, the second opening 24B exposes a portion of the high-k dielectric layer 26 that is right above the second photodiode 22B such that the second photodiode 22B can be further exposed after the portion of the high-k dielectric layer 26 is removed in a subsequent process.

In this embodiment, the light-absorbing layer 25 is a silicon oxynitride (SiON) layer which preferably has a thickness of 200 Å to 700 Å. For example, the SiON layer may have a thickness of 200 Å, 250 Å, 300 Å, 350 Å, 400 Å, 450 Å, 500 Å, 550 Å, 600 Å, 650 Å, or 700 Å. The SiON layer with such a thickness not only ensures a relatively thin light-absorbing layer 25, thus contributing to the thinness and miniaturization of the BSI CMOS image sensor, but also prevents light from being reflected by the side face 241 of the opening 24 into another photodiode 22 other than the photodiode 22 corresponding to the opening 24, thereby preventing the occurrence of photon cross-talk and improving imaging quality of the BSI CMOS image sensor. Moreover, the light-absorbing layer 25 may be formed by a plasma enhanced chemical vapor deposition (PECVD) process, or alternatively by other semiconductor processes, such as a furnace process.

Furthermore, in other embodiments of the present invention, the light-absorbing layer 25 may be formed of other nitride layers, such as a silicon nitride (SiN) layer, a titanium nitride (TiN) layer or a tantalum nitride (TaN) layer. Preferably, the nitride layer has a thickness of 200 Å to 700 Å and is formed by a PECVD process or a furnace process.

While in the illustrated embodiment, the light-absorbing layer 25 is formed only on the side faces of the opening 24, in other embodiments of the present invention, the light-absorbing layer 25 may also be formed on a top face of the metal shielding layer 23 (as described per the profile and orientation of the opening shown in FIG. 1) or on a remaining exposed surface portion of the metal shielding layer 23.

### Embodiment 2

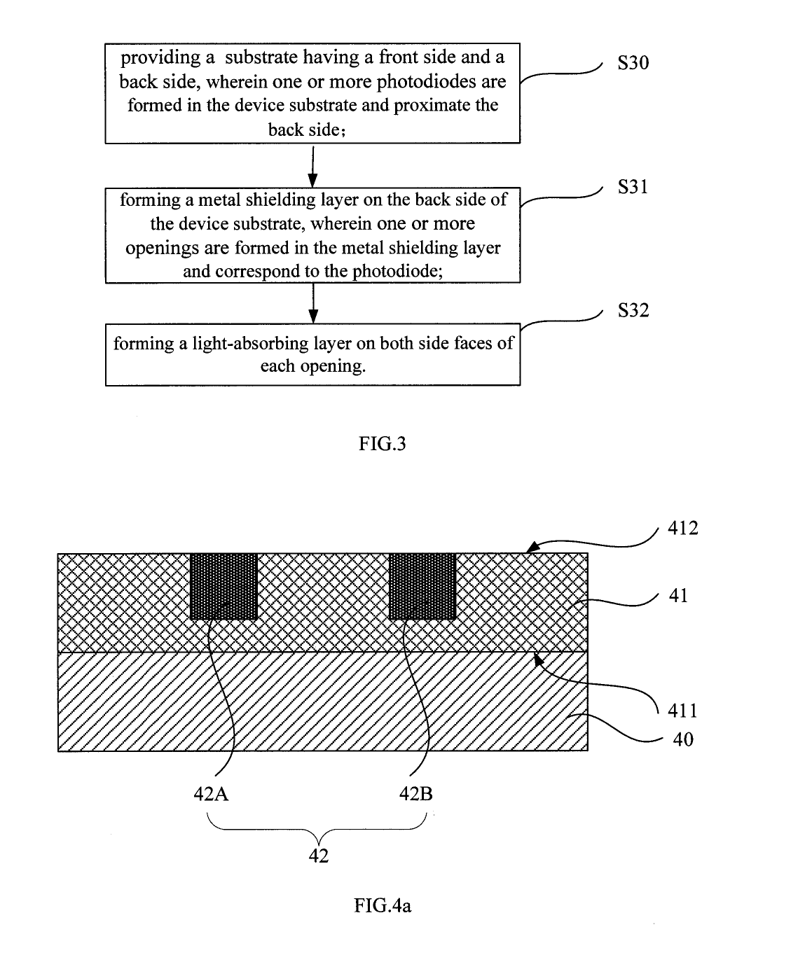

In this disclosure there is also provided a method of forming a BSI CMOS image sensor, a flow chart of which is illustrated in FIG. 3. The method includes the steps of providing a device substrate having a front side and a back side, wherein one or more photodiodes are formed in the device substrate and proximate the back side; forming a metal shielding layer on the back side of the device substrate, wherein one or more openings are formed in the metal shielding layer and correspond to the photodiodes; and forming a light-absorbing layer on both side faces of each opening.

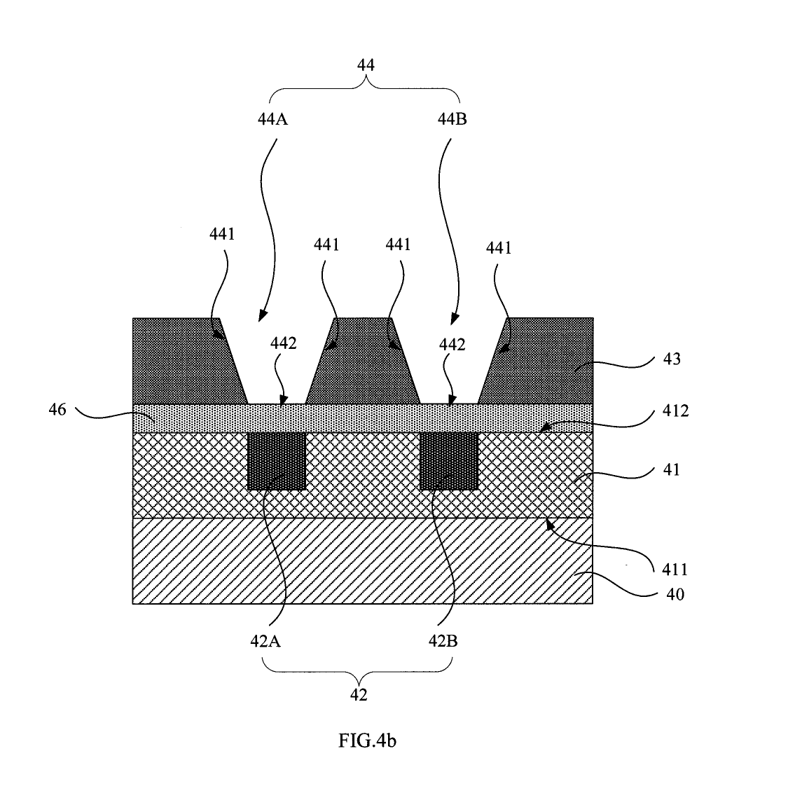

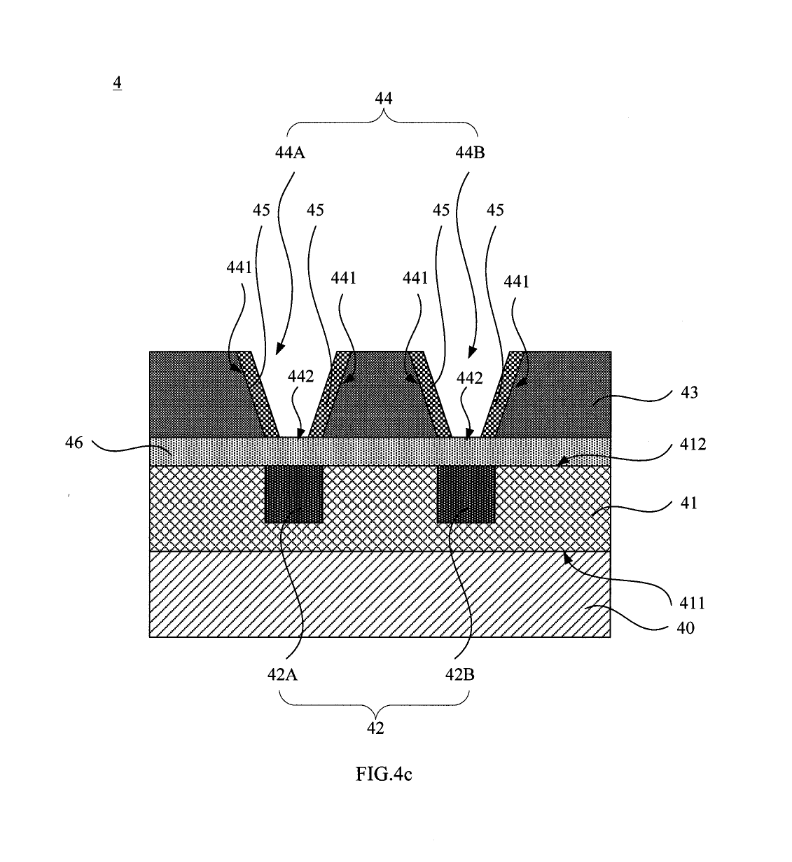

FIGS. 4a to 4c are cross-sectional views schematically illustrating structures after steps of the method in this embodiment.

FIG. 4a shows the device substrate 41 which has a front side 411 and a back side 412. Two of the photodiode 42, a first photodiode 42A and a second photodiode 42B, are formed in the device substrate 41 and both proximate the back side 412 of the device substrate 41.

In this embodiment, the device substrate 41 is bonded to a carrier substrate 40, specifically in a manner that the front side 411 of the device substrate 41 is bonded to the carrier substrate 40. Moreover, the backside 412 of the device substrate 41 that is bonded to the carrier substrate 40 is thinned by grinding and wet etching.

FIG. 4b shows a resulting structure after a high-k dielectric layer 46 is formed on the thinned backside 412 of the device substrate 41, a metal shielding layer 43 is formed on the high-k dielectric layer 46, one or more openings 44 (two as shown in the figure) are formed in the metal shielding layer 43 using a dry etching process. The metal shielding layer 43 may be comprised of aluminum or tungsten. An angle between the side face 441 and the bottom face 442 of the opening 44 is greater than 90 degrees and smaller than 180 degrees. The opening 44 exposes a portion of the underlying high-k dielectric layer 46.

FIG. 4b shows two of the openings 44, namely a first opening 44A that corresponds to the first photodiode 42A and a second opening 44B that corresponds to a second photodiode 22B. Preferably, the first and second openings 44A, 44B are vertically aligned with the first and second photodiodes 42A, 42B respectively.

FIG. 3 shows a resulting structure after a light-absorbing layer 45 is formed on both side faces 441 of each opening 44. Preferably, the light-absorbing layer 45 is a nitride layer such as a SiON, SiN, TiN, or TaN layer. The light-absorbing layer 45 may have a thickness of 200 Å to 700 Å and is formed by a PECVD process or a furnace process.

Forming the light-absorbing layers 45 may include: forming a layer of a light-absorbing material, covering both the metal shielding layer 43 (i.e., covering the side faces 441 of the first and second openings 44A, 44B and a top surface of the metal shielding layer 43) and the exposed portions of the high-k dielectric layer 46; and removing the light-absorbing material over the portions of the high-k dielectric layer 46 using a photolithography-and-etching process to form a light-absorbing layer 45 over each of the side faces 441 of the first and second openings 44A, 44B and the top surface of the metal shielding layer 43, or removing the light-absorbing material over the portions of the high-k dielectric layer 46 and the top surface of the metal shielding layer 43 using a photolithography-and-etching process to form a light-absorbing layer 45 over each of the side faces 441 of the first and second openings 44A, 44B.

Forming the light-absorbing layer 45 can prevent light from being reflected by the side face 441 of the opening 24 into another photodiode 22 other than the photodiode 22 corresponding to the opening 24, thereby preventing the occurrence of photon cross-talk and improving imaging quality of the BSI CMOS image sensor.

Whilst there has been described in the foregoing description specific embodiments of the present invention, it will be understood by those skilled in the technology concerned that many variations or modifications may be made according to the present teachings. Accordingly, it is intended that the appended claims embrace all such modifications and variations as falling within the true scope of the present invention.

What is claimed is:

1. A backside illuminated (BSI) CMOS image sensor, comprising:
a substrate having a front side and a back side, the substrate including a photodiode formed therein, the photodiode being proximate the back side of the substrate;
a metal shielding layer covering the back side of the substrate, the metal shielding layer including an opening formed therein, the opening being arranged in correspondence with the photodiode; and
a light-absorbing layer formed on each side face of the opening.

2. The BSI CMOS image sensor according to claim 1, wherein the opening is vertically aligned with the photodiode.

3. The BSI CMOS image sensor according to claim 1, further comprising a high-k dielectric layer between the substrate and the metal shielding layer.

4. The BSI CMOS image sensor according to claim 3, wherein a portion of the high-k dielectric layer is exposed in the opening.

5. The BSI CMOS image sensor according to claim 1, wherein the light-absorbing layer is a nitride layer.

6. The BSI CMOS image sensor according to claim 5, wherein the light-absorbing layer is a silicon oxynitride layer, a silicon nitride layer, a titanium nitride layer, or a tantalum nitride layer.

7. The BSI CMOS image sensor according to claim 5, wherein the light-absorbing layer has a thickness of 200 Å to 700 Å.

8. The BSI CMOS image sensor according to claim 1, wherein the light-absorbing layer is formed by a PECVD process or a furnace process.

9. The BSI CMOS image sensor according to claim 1, wherein an angle between the side face and a bottom face of the opening is greater than 90 degrees and smaller than 180 degrees.

10. The BSI CMOS image sensor according to claim 1, wherein a top face of the metal shielding layer is also covered by the light-absorbing layer.

11. The BSI CMOS image sensor according to claim 1, wherein the metal shielding layer is made of aluminum or tungsten.
